(19) United States
(12) Patent Application Publication
(10) Pub. No.: US 2019/0123122 A1
(43) Pub. Date: Apr. 25, 2019

(54) DISPLAY PANEL AND DISPLAY APPARATUS USING THE SAME

(71) Applicants: HKC Corporation Limited, Chongqing (CN); Chongqing HKC Optoelectronics Technology Co., Limited, Chongqing (CN)

(72) Inventor: Yu-Jen CHEN, Chongqing (CN)

(21) Appl. No.: 15/555,382

(22) PCT Filed: Jul. 7, 2017
(86) PCT No.: PCT/CN2017/092229

§ 371 Date: Sep. 1, 2017

(30) Foreign Application Priority Data
Jun. 8, 2017 (CN) 20170429053.9

(51) Int. Cl. H01L 27/32; G02F 1/1362

(52) U.S. Cl. CPC H01L 27/3272; G02F 2001/136222; G02F 1/136209; H01L 27/322

(57) ABSTRACT

Disclosed is a display panel and a display apparatus using the same. The display panel includes: a first substrate, comprising an external and an internal surfaces; a second substrate, disposed opposite to the first substrate, and having an external and an internal surfaces; a color light filtering layer, disposed on the internal surface of the first or of the second substrate in an arrayed pattern; and a light shielding layer, disposed on the external surface of the first substrate, and including a first light shielding layer disposed at an edge of the first substrate, and a second light shielding layer arrayed on an internal side of the edge of the first substrate, the second light shielding layer being surrounded by the first light shielding layer; wherein the second light shielding layer is disposed corresponding to a gap of the arrayed pattern of the color light filtering layer.

### BACKGROUND

### Technical Field

This application relates to a display panel and a display apparatus using the same, and in particular, to a position where a light shielding layer of a substrate of a display panel having no bezel is formed.

### Related Art

Planar display panels have currently become the mainstream of the display market, and a traditional planar display panel, for example, a backlight liquid crystal display, includes a liquid crystal display panel and a backlight module (Backlight Module). The liquid crystal display panel includes: a first substrate—a switch array substrate (TFT, Thin Film Transistor), a second substrate—a color film substrate (CF, Color Filter), and liquid crystals (LC, Liquid Crystal) sandwiched between the color film substrate and the switch array substrate. Even display apparatuses such as self light emitting display panels OLED and QLED without backlight modules have been developed to ensure a lighter and thinner appearance. To satisfy the current appearance requirement on planar displays on the market, planar display panels start to develop towards a bezel-less design, to highlight a sense of unity of a display picture. However, after a bezel is removed, a lateral light leakage problem at an edge needs to be resolved; otherwise, a peripheral light leakage phenomenon appears. In addition, when a product having no bezel on four sides displays a panel array upwards laterally, surrounding metal ray reflection results in an undesirable visual sense, and panel quality is affected. Therefore, how to enable rays to be seen evenly and resolve the lateral light leakage problem at an edge is an important reference factor of a large-size panel.

Generally, in a process of a switch array substrate or a color film substrate of a display panel, a light shielding layer (generally, a black matrix (BM) is used) is formed within the switch array substrate or the color film substrate, and is used to be disposed between RGB (red green blue) light filter layers of color display pictures, or is used to shield from a light source, avoid color mixing, improve color comparison, and the like. However, to resolve the lateral light leakage problem at an edge, a process for a black matrix to be formed at an edge of the switch array substrate needs to be added to shield from lateral light leakage at the edge.

### SUMMARY

To resolve the foregoing technical problem, an objective of this application is to provide a display panel and a display apparatus using the same, and in particular, relates to a position where a light shielding layer of a substrate of a display panel having no bezel is formed. In this way, metal ray reflection around a switch array substrate can be absorbed, and the problem of an undesirable visual sense caused by metal ray reflection is resolved. In addition, labor, material, and time costs generated for forming a black matrix used as a light shielding layer can be avoided in a process. Due to the black matrix can shield from a light source, avoid color mixing, and improve color comparison and therefore there is no need for a color light filtering layer to dispose a black matrix between first color light filter, a second color light filter, and a third color light filter, thereby avoiding process costs of a black matrix. Meanwhile, the black matrix conforming to a pattern of an enclosed curve of a bezel of a first substrate can be used to shield from light leakage at an edge of the switch array substrate. That is, in this application, after a black matrix on a side of a color film substrate is moved to an external side of the switch array substrate, the black matrix may absorb metal ray reflection around the switch array substrate and the color film substrate, thereby resolving an undesirable visual sense caused by metal ray reflection.

The objective of this application is achieved and the technical problem of this application is resolved by using the following technical solutions. This application provides a display panel, comprising: a first substrate, comprising an external surface and an internal surface; a second substrate, disposed opposite to the first substrate, and having an external surface and an internal surface; a color light filtering layer, disposed on the internal surface either of the first substrate or of the first substrate in an arrayed pattern; and a light shielding layer, disposed on the external surface of the first substrate, wherein the light shielding layer comprises a first light shielding layer disposed at an edge of the first substrate, and a second light shielding layer arrayed on an internal side of the edge of the first substrate, the second light shielding layer being surrounded by the first light shielding layer; wherein the second light shielding layer is disposed corresponding to a gap of the arrayed pattern of the color light filtering layer.

In an embodiment of this application, the light shielding layer is a black matrix.

In an embodiment of this application, the color light filtering layer comprises a first color light filter, a second color light filter formed in parallel.

In an embodiment of this application, the first color light filter is a red light filter, the second color light filter is a green light filter, and the third color light filter is a blue light filter.

In an embodiment of this application, the black matrix is a photosensitive resin material or a metal material.

In an embodiment of this application, the first substrate is a switch array substrate.

In an embodiment of this application, the second substrate is a color light filter substrate.

In an embodiment of this application, a flat layer is further included, and is disposed on the external surface of the first substrate.

Another objective of this application is to provide a display apparatus, including: a backlight module; and a display panel, comprising: a first substrate, comprising an external surface and an internal surface; a second substrate, disposed opposite to the first substrate, and having an external surface and an internal surface; a color light filtering layer, disposed on the internal surface either of the first substrate or of the second substrate in an arrayed pattern; and a light shielding layer, disposed on the external surface of the first substrate, wherein the light shielding layer comprises a first light shielding layer disposed at an edge of the first substrate, and a second light shielding layer arrayed on an internal side of the edge of the first substrate, the second light shielding layer being surrounded by the first light shielding layer; wherein the second light shielding layer is disposed corresponding to a gap of the arrayed pattern of the color light filtering layer.

In an embodiment of this application, the light shielding layer is a black matrix.

In an embodiment of this application, the color light filtering layer comprises a first color light filter, a second color light filter and a third color light filter formed in parallel.

In an embodiment of this application, the first color light filter is a red light filter, the second color light filter is a green light filter, and the third color light filter is a blue light filter.

In an embodiment of this application, the black matrix is a photosensitive resin material or a metal material.

In an embodiment of this application, the first substrate is a switch array substrate.

In an embodiment of this application, the second substrate is a color light filter substrate.

In an embodiment of this application, a flat layer is further included, and is disposed on the external surface of the first substrate.

Alternatively, the objective of this application may be achieved and the technical problem of this application may be resolved by using the following technical solutions. A display panel includes: a first substrate, comprising an external surface and an internal surface; a color light filtering layer, disposed on the internal surface of the first substrate in an arrayed pattern; and a light shielding layer, disposed on the external surface of the first substrate, wherein the light shielding layer comprises a first light shielding layer disposed at an edge of the first substrate, and a second light shielding layer arrayed on an internal side of the edge of the first substrate, the second light shielding layer being surrounded by the first light shielding layer; wherein the second light shielding layer is disposed corresponding a gap of the arrayed pattern of the color light filtering layer, wherein the light shielding layer is a black matrix, and the black matrix is photosensitive resin material or a metal material; wherein the color light filtering layer comprises a first color light filter, a second color light filter and a third color light filter formed in parallel, and the first color light filter is a red light filter, the second color light filter is a green light filter, and the third color light filter is a blue light filter.

In this application, not only metal ray reflection around a switch array glass substrate can be absorbed, and the problem of an undesirable visual sense caused by metal ray reflection is resolved, but also the labor, material, and time costs generated for forming a black matrix at a side of a color film substrate. In addition, after a black matrix on a side of a color film substrate is moved to an external side of the switch array substrate, the black matrix can shield from a light source, avoid color mixing, and improve color comparison and can absorb metal ray reflection around the switch array glass substrate, thereby resolving an undesirable visual sense caused by metal ray reflection.

### BRIEF DESCRIPTION OF THE DRAWINGS

FIG. 1a is a schematic structural diagram of an exemplary display panel;

FIG. 1b is a schematic structural diagram of another exemplary display panel;

FIG. 2a is a schematic diagram of forming a light shielding layer on a bezel of a first substrate according to an embodiment of this application;

FIG. 2b is a schematic diagram of forming a light shielding layer in arrays on a bezel of a first substrate and within the first substrate according to another embodiment of this application;

FIG. 2c is a schematic diagram of including a flat layer between a polarizer and a light shielding layer according to another embodiment of this application;

FIG. 2d is a schematic diagram of stacking color light filters on a bezel of a first substrate to form a light shielding layer according to an embodiment of this application;

FIG. 2e is a schematic diagram of stacking color light filters in arrays at an edge of a first substrate and within the first substrate to form a light shielding layer according to another embodiment of this application;

FIG. 2f is a schematic diagram of including a flat layer between a polarizer and a light shielding layer by stacking color light filters according to another embodiment of this application;

FIG. 3a is a schematic structural diagram of combining a direct-lit backlight module according to an embodiment of this application;

FIG. 3b is a schematic structural diagram of combining an edge-lit backlight module according to an embodiment of this application;

FIG. 3c is a schematic structural diagram of combining a direct-lit backlight module according to another embodiment of this application;

FIG. 3d is a schematic structural diagram of combining an edge-lit backlight module according to another embodiment of this application;

FIG. 4a is a schematic structural diagram of combining a direct-lit backlight module according to another embodiment of this application;

FIG. 4b is a schematic structural diagram of combining an edge-lit backlight module according to another embodiment of this application;

FIG. 4c is a schematic structural diagram of combining a direct-lit backlight module according to another embodiment of this application; and

FIG. 4d is a schematic structural diagram of combining an edge-lit backlight module according to another embodiment of this application.

### DETAILED DESCRIPTION

The following embodiments are described with reference to accompanying drawings, to provide examples of particular implementable embodiments of this application. Direction terms described in this application, for example, “above”, “below”, “front”, “behind”, “left”, “right”, “internal”, “external”, and “lateral face” indicate only directions with reference to accompanying drawings. Therefore, direction terms used are intended to describe and understand this application, instead of limiting this application.

Accompanying drawings and descriptions are considered as essentially illustrative instead of limitative. In drawings, modules having similar structures are indicated by a same reference number. In addition, for ease of understanding and description, sizes and thicknesses of components shown in the accompanying drawings are randomly shown, but this application is not limited thereto.

In the accompanying drawings, for the purpose of clarity, thicknesses of layers, sheets, substrates, and the like are enlarged. In the accompanying drawings, for ease of understanding and description, thicknesses of layers and sheets are enlarged. It should be understood that, when it is described that components such as layers, sheets, or substrates are located “on” another component, the component may be directly located on the another component, or there may be a component therebetween.

In addition, in this specification, unless otherwise described clearly, the term “include” shall be understood as including a component, but not excluding any other components. In addition, in this specification, “on” means that a component is located above or below a target component, and does not mean that a component needs to be located on the top based on a gravity direction.

To further describe technical means used in this application to achieve a preset application objective and technical effects of this application, the following describes, with reference to the accompanying drawings and preferred embodiments, in detail specific implementations, structures, features, and effects of a display panel and a display apparatus using the same provided based on this application.

A display panel combining two glass substrates to display numbers or images is used for a planar display, and may be classified into a liquid crystal display panel incapable of emitting light and a self light emitting display panel. The liquid crystal display panel cannot emit light; therefore, a backlight module is needed to provide a ray. A picture is formed by controlling light transfer of a liquid crystal display panel. Liquid crystals are evenly disposed in the liquid crystal display panel.

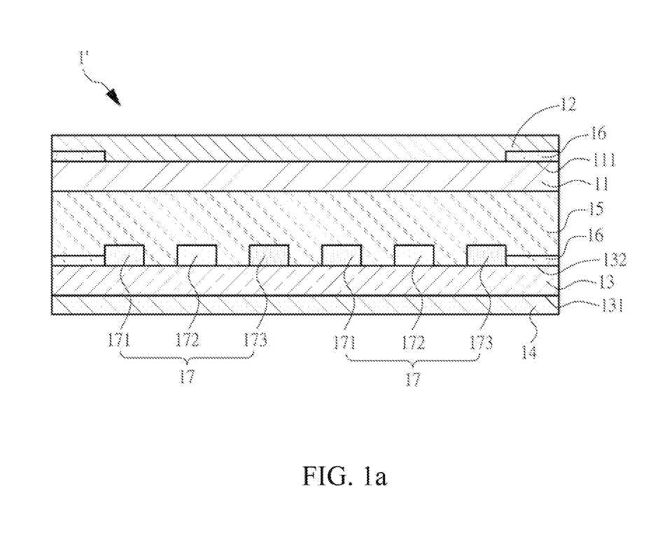

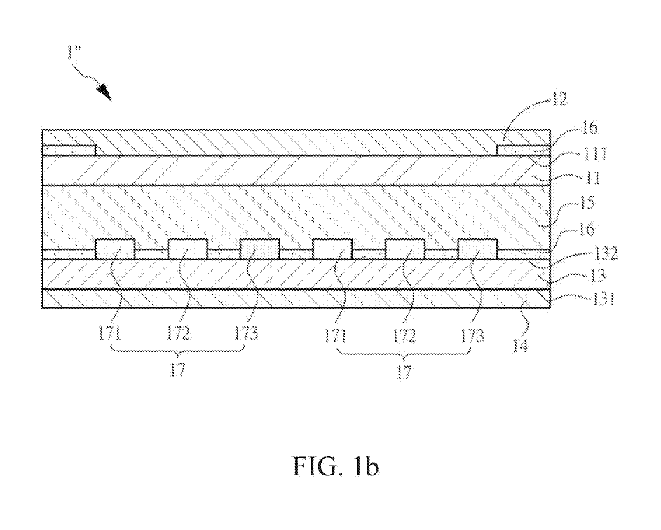

As shown in schematic structural diagrams, an exemplary display panel 1′ of FIG. 1a and an exemplary display panel 1″ of FIG. 1b mainly include a first substrate 11, a second substrate 13, and a bonding layer 15 disposed therebetween. The bonding layer 15 is used to bond the first substrate 11 and the second substrate 13, and provide an accommodation space having an interval height, so that components may be disposed on opposite bonded surfaces of the first substrate 11 and the second substrate 13. A light shielding 16 is formed on an external surface 111 of the first substrate 11 to absorb metal ray reflection around the first substrate 11 (for example, a switch array substrate), and resolve the problem of an undesirable visual sense caused by metal ray reflection. The exemplary display panel 1′ of FIG. 1a is a pattern conforming to an enclosed curve of a bezel of the first substrate 11, and the exemplary display panel 1″ of FIG. 1b is a pattern conforming to a bezel of the first substrate 11 and being arrayed within a range of the enclosed curve.

Generally, the second substrate 13 is a color light filter substrate; therefore, a color light filtering layer 17 is formed on an internal surface 132 of the second substrate 13. The color light filtering layer 17 includes a first color light filter 171, a second color light filter 172, and a third color light filter 173 formed in parallel.

In addition, a first polarizer 12 and a second polarizer 14 are disposed on an external side of the external surface 111 of the first substrate 11 and an external side of the external surface 131 of the second substrate 13, to control a polarization direction of a ray so that the display panel achieves shading in display in an externally applied electric field. That is, the light shielding layer 16 is formed on an internal surface 132 of the second substrate 13 of the exemplary display panel 1″ and disposed between RGB (red green blue) light filter layers for shielding from a light source, avoid color mixing, improve color comparison. However, the light shielding layer 16 formed on the external surface 111 of the first substrate 11 and the internal surface 132 of the second substrate 13 is of a same material and consequently forming the light shielding layer 16 on the external surface 111 of the first substrate 11 increases a process cost.

A basic structure of the display panel includes the first substrate 11, the second substrate 13, and the bonding layer 15 formed between the two substrates.

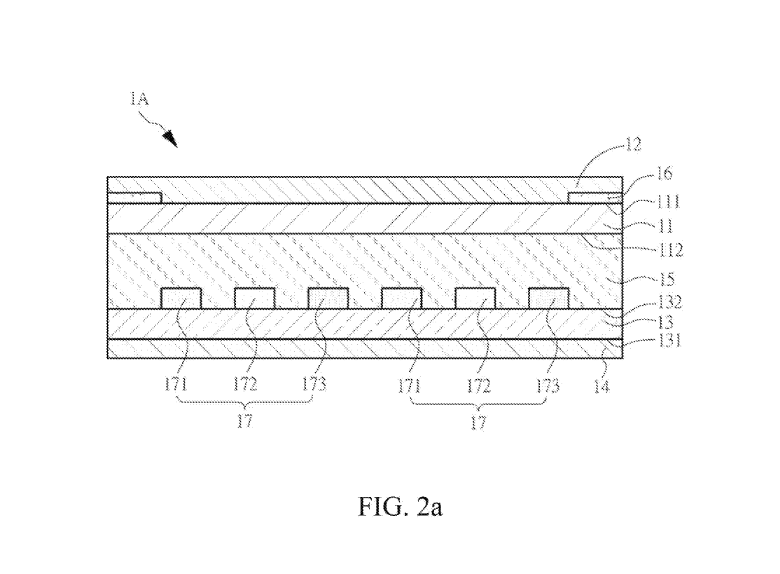

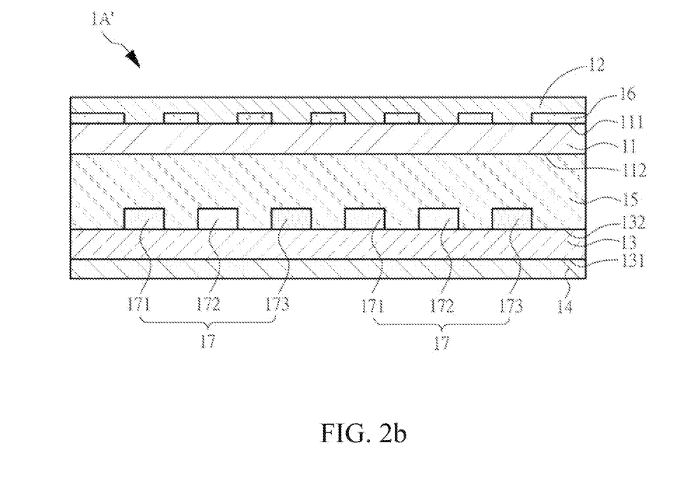

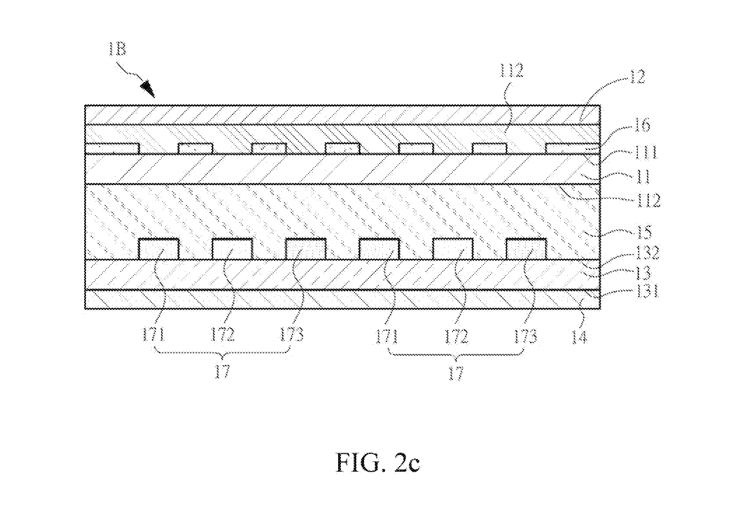

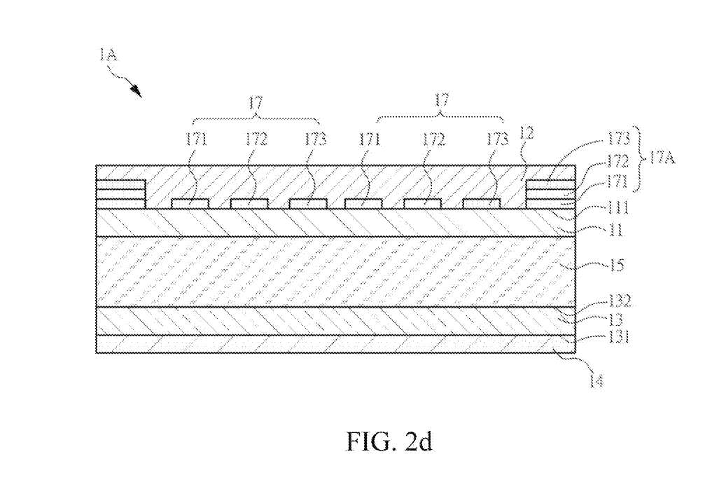

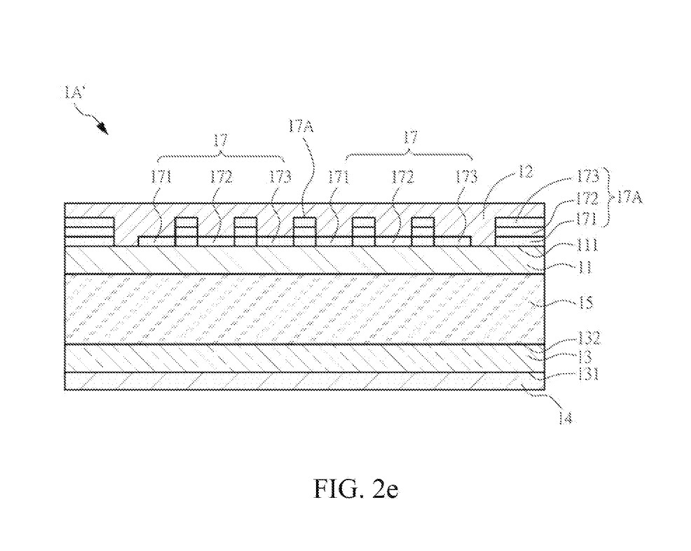

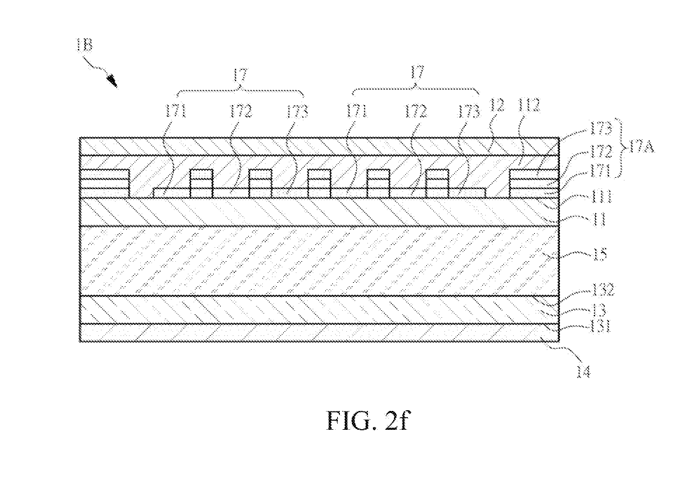

As shown in FIG. 2a to FIG. 2c, in an embodiment, the display panel of this application may be a display panel having no bezel.

FIG. 2a and FIG. 2b are schematic diagrams of forming a light shielding layer in two forms according to embodiments of this application. In an embodiment of this application, a display panel 1A and a display panel 1A′ each include: a first substrate 11, including an external surface 111 and an internal surface 112; a first polarizer 12, disposed on the external surface 111 of the first substrate 11; a second substrate 13, disposed opposite to the first substrate 11, and having an external surface 131 and an internal surface 132; a second polarizer 14, disposed on the external surface 131 of the second substrate 13; a color light filtering layer 17, formed in an arrayed pattern on the internal surface 112 of the first substrate 11 or on the internal surface 132 of the second substrate 13; and a bonding layer 15, disposed between the internal surface 112 of the first substrate 11 and the internal surface 132 of the second substrate 13; and a light shielding layer 16, formed on the external surface 111 of the first substrate 11 in a form of the first light shielding layer (for example, annular-shaped) conforming to the pattern of an edge of the first substrate 11 (the display panel 1A), and in a form of the second light shielding layer (for example, board-shaped or lattice-shaped) having a pattern arrayed on an internal side of the edge the display panel 1A′. The second light shielding layer is surrounded by the first light shielding layer and the second light shielding layer is disposed corresponding to a gap of the arrayed pattern of the color light filtering layer 17.

In an embodiment, when the light shielding layer 16 is disposed on an external surface 111 of the first substrate 11, the light shielding layer 16 is located between the first substrate 11 and the first polarizer 12, and the light shielding layer 16 can be, for example, a black matrix.

In an embodiment, a color light filtering layer 17 is further included. The color light filtering layer 17 is disposed on the internal surface 132 of the second substrate 13 (in another embodiment, the light filtering layer 17 may be disposed on the internal surface 112 of the first substrate 11) and the color light filtering layer 17 includes the first color light filter 171, the second color light filter 172, and the third color light filter 173 are formed in parallel.

In an embodiment, the first color light filter 171 is a red light filter, the second color light filter 172 is a green light filter, and the third color light filter 173 is a blue light filter.

The light shielding layer 16 having a pattern arrayed within an enclosed curve can shield from a light source, avoid color mixing, and improve color comparison and therefore there is no need for the color light filtering layer 17 to dispose a light shielding layer between first color light filter, a second color light filter, and a third color light filter, thereby avoiding process costs of a light shielding layer. Meanwhile, the light shielding layer 16 conforming to a pattern of an enclosed curve of a bezel of a first substrate 11 can be used to shield from light leakage at an edge of the switch array substrate.

In an embodiment, the black matrix is an organic insulation material (a photosensitive resin material or a metal material).

In an embodiment, the first substrate 11 is a switch array substrate, and the second substrate 12 is a color light filter substrate.

FIG. 2c is a schematic diagram of including a flat layer between a polarizer and a light shielding layer according to an embodiment of this application. Different from FIG. 2a and FIG. 2b, in the embodiment of FIG. 2c, a flat layer 112 is further included. Referring to FIG. 2c, in an embodiment of the present application, a display panel 1B includes a flat layer 112, and further includes the display panel 1A′. The flat layer 112 is a smooth protective layer used to protect the light shielding layer 16 coated and formed on the external surface 111 of the first substrate 11.

In another embodiment, the application is equivalent to the structures of FIG. 2a to FIG. 2c, the first color light filter 171, the second color light filter 172, and the third color light filter 173 are moved to the external surface 111 of the first substrate 11, and, by stacking the color light filters, a same effect of a light shielding layer 17A is reached. As shown in FIG. 2d to FIG. 2f, same components are indicated by a same reference numeral. A display panel 1A and a display panel 1A′ in FIG. 2d and FIG. 2e each include: a first substrate 11, including an external surface 111 and an internal surface 112; a first polarizer 12, disposed on the external surface 111 of the first substrate 11; a second substrate 13, disposed opposite to the first substrate 11, and including an external surface 131 and an internal surface 132; a second polarizer 14, disposed on the external surface 131 of the second substrate 13; a bonding layer 15, disposed between the first substrate 11 and the second substrate 13; a color light filtering layer 17, where the color light filtering layer 17 is disposed on the external surface 111 of the first substrate 11, and the color light filtering layer 17 includes a first color light filter 171, a second color light filter 172 and a third color light filter 173 are formed in parallel; and a light shielding layer 17A, formed by stacking the color light filters 171, 172, 173. FIG. 2f is equivalent to the structure of FIG. 2c, where a flat layer 112 is formed between the light shielding layer 17A and the first polarizer 12.

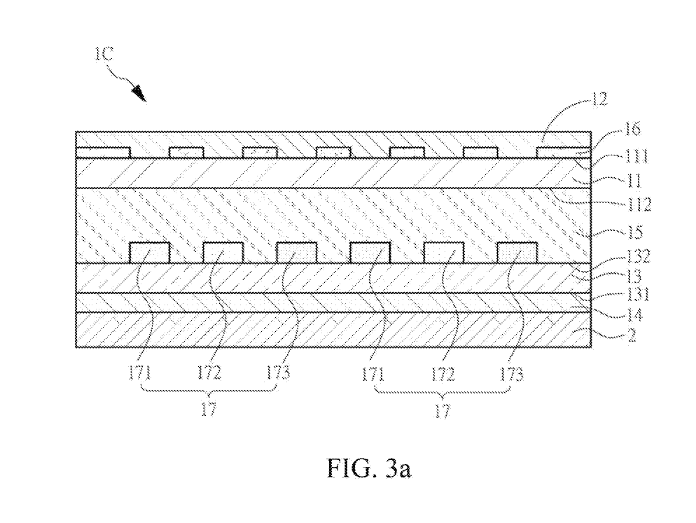

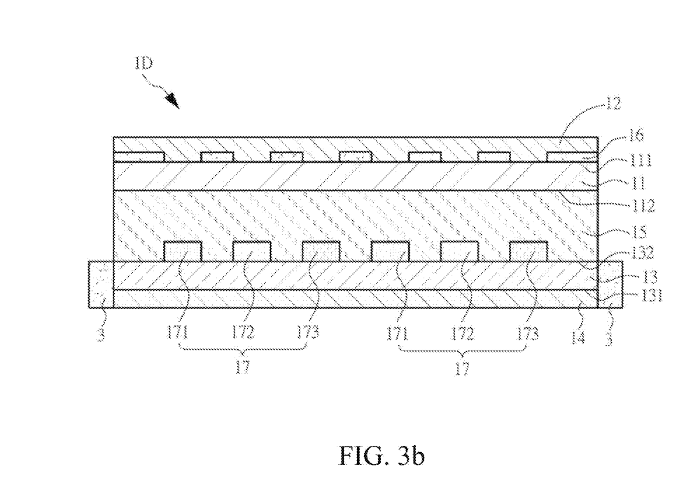

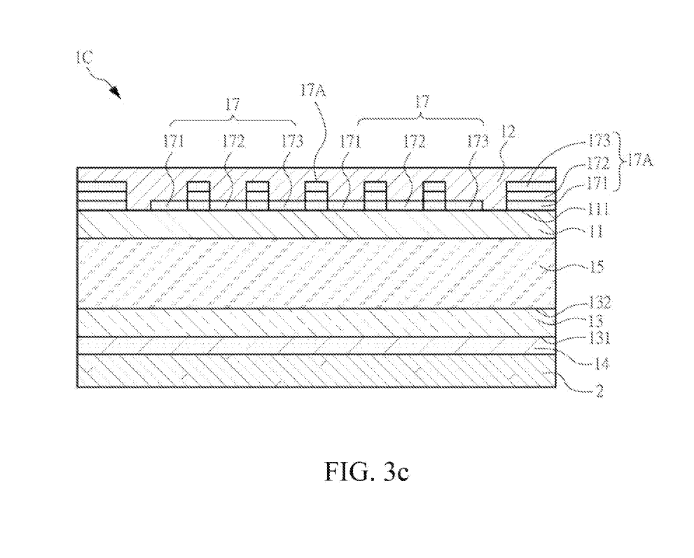

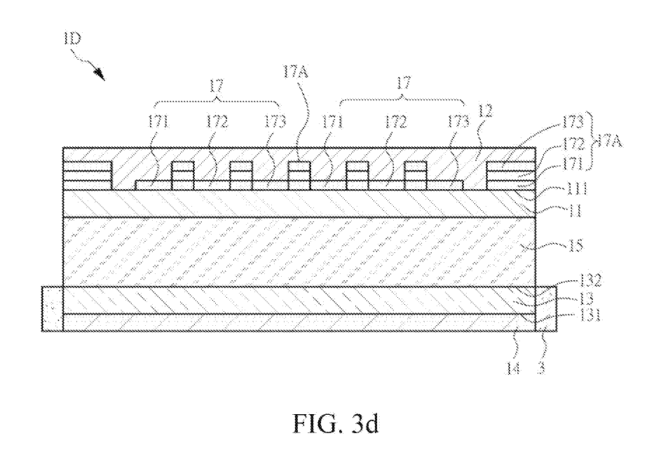

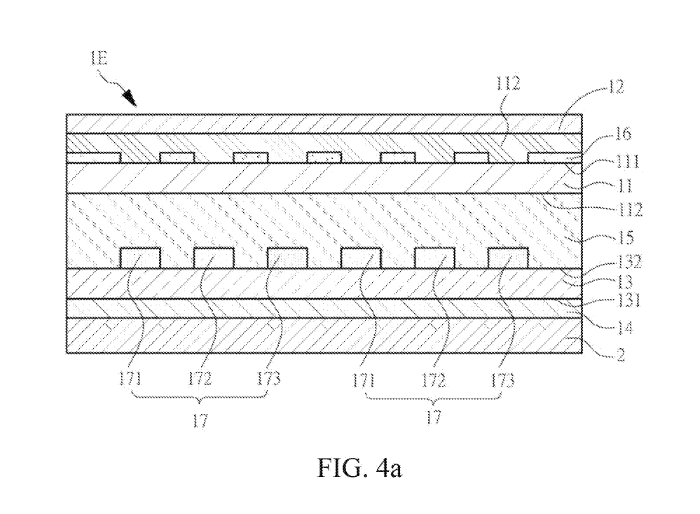

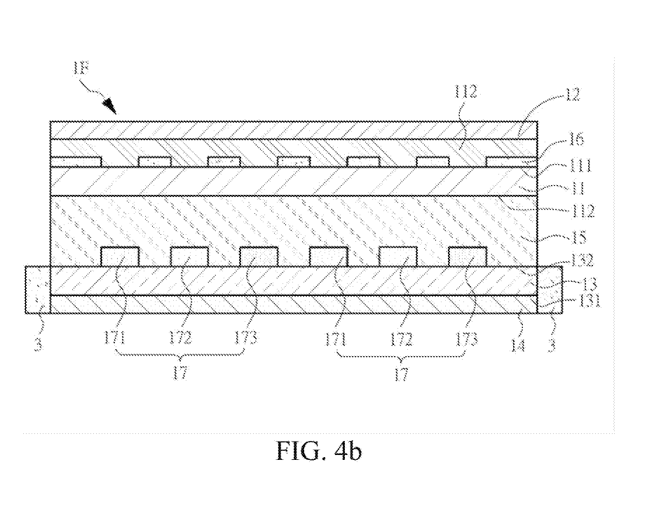

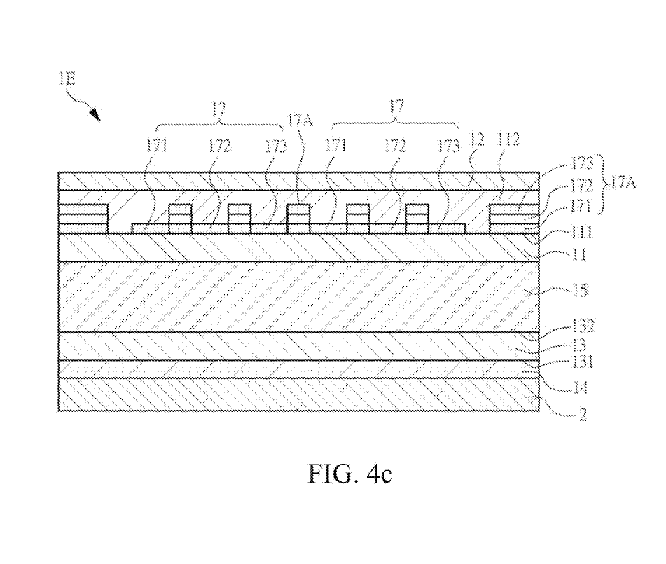

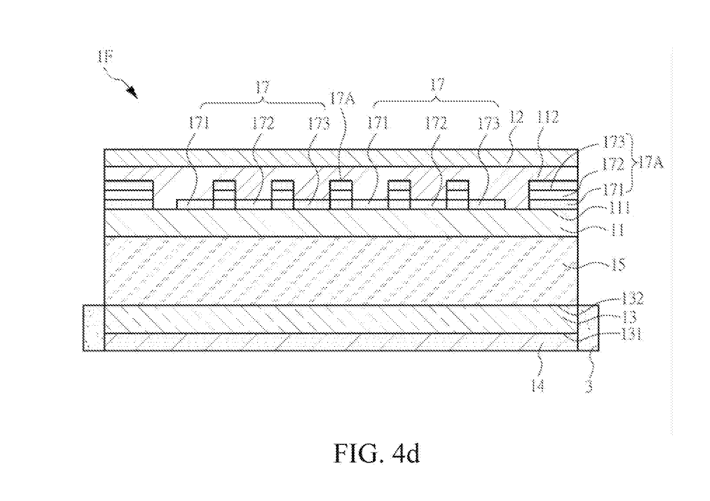

As illustrated in FIG. 3a to FIG. 4b, the display panel of this application may further be combined with a direct-lit backlight module 2 and an edge-lit backlight module 3 to form a display apparatus.

Referring to FIG. 3a and FIG. 3b, FIG. 3a is a schematic structural diagram of combining a direct-lit backlight module according to an embodiment of this application. In an embodiment, a display apparatus IC includes a direct-lit backlight module 2, and further includes the display panel 1A′. The direct-lit backlight module 2 means that LED dies are evenly disposed behind the display panel 1A′ to serve as a light emitting source, so that backlight can evenly transfer to the entire screen. For an embodiment equivalent to the structure of FIG. 3a, refer to FIG. 3c. In FIG. 3c, the difference from FIG. 3a is that the light shielding layer 17A is formed by stacking color light filters moved to the external surface 111 of the first substrate 11.

Referring to FIG. 3b and FIG. 3d, FIG. 3b is a schematic structural diagram of combining an edge-lit backlight module according to a first embodiment of this application. In an embodiment, a display apparatus ID includes an edge-lit backlight module 3, and further includes the display panel 1A′. The edge-lit backlight module 3 means that LED dies are disposed at an edge surrounding the display panel 1A′, and a light guide technology is used, so that when the backlight module emits light, light emitted from an edge of a screen is transferred to the central area of the screen by using the light guide technology. In this way, the entire screen has sufficient backlight, and the display panel 1A′ can display a picture. For an embodiment equivalent to the structure of FIG. 3b, refer to FIG. 3d. In FIG. 3d, the difference from FIG. 3b is that the light shielding layer 17A is formed by stacking color light filters moved to the external surface 111 of the first substrate 11.

Referring to FIG. 4a, 4d, FIG. 4a is a schematic structural diagram of combining a direct-lit backlight module according to an embodiment of this application. In an embodiment, a display apparatus 1E includes a direct-lit backlight module 2, and further includes the display panel 1B. FIG. 3a and FIG. 4a both include the direct-lit backlight module 2, and a difference lies in that the display apparatus 1E used in FIG. 4a is a display structure with a flat layer 112. FIG. 4c is equivalent to the structure of FIG. 4a, and the difference is that the light shielding layer 17A in FIG. 4c is formed by stacking color light filters moved to the external surface 111 of the first substrate 11.

Referring to FIG. 4b and FIG. 4d, FIG. 4b is a schematic structural diagram of combining an edge-lit backlight module according to an embodiment of this application. In an embodiment, a display apparatus 1F includes an edge-lit backlight module 3, and further includes the display panel 1B. FIG. 3b and FIG. 4b both include the edge-lit backlight module 3, and a difference lies in that the display 1B of the display apparatus 1F in FIG. 4b is a display structure with a flat layer 112. FIG. 4d is equivalent to the structure of FIG. 4b, and the difference is that the light shielding layer 17A in FIG. 4d is formed by stacking color light filters moved to the external surface 111 of the first substrate 11.

In different embodiments, the display panel may also be, for example, a liquid crystal display panel, an OLED display panel, a QLED display panel, a curved-surface display panel, or another display panel, and the display panel is not limited.

In an embodiment, the display panel of this application may be applied to a self light emitting display panel such as an OLED and a QLED, and a display device. The display panel includes: a first substrate 11, including an external surface 111 and an internal surface 112; a color light filtering layer 17, formed on the external surface 111 of the first substrate 11 in an arrayed pattern, and a light shielding layer 16, including a first light shielding layer disposed on an edge of the first substrate 11 and a second light shielding layer arrayed an internal side of the edge of the first substrate 11, where the second light shielding layer is surrounded by the first light shielding layer and the second light shielding layer is disposed corresponding to a gap of an arrayed pattern of the color light filter 17.

In this application, not only metal ray reflection around a switch array glass substrate can be absorbed, and the problem of an undesirable visual sense caused by metal ray reflection is resolved and also labor, material, and time costs generated for forming a black matrix at a side of a color film substrate. In addition, after a black matrix on a side of a color film substrate is moved to an external side of the switch array substrate, the black matrix can shield from a light source, avoid color mixing, and improve color comparison and can absorb metal ray reflection around the switch array glass substrate, thereby resolving an undesirable visual sense caused by metal ray reflection.

Phrases such as “in some embodiments” and “in various embodiments” are repeatedly used. The phrases generally do not indicate same embodiments, but may also indicate same embodiments. Unless otherwise described in context, terms such as “include”, “have”, and “comprise” are synonyms.

Only specific embodiments of the present invention are provided above, and are not intended to limit this application in any form. Although specific embodiments of this application are disclosed above, the specific embodiments of this application are not intended to limit this application. Any person skilled in the art may change or embellish the technical content disclosed above to obtain equivalent embodiments without departing from the scope of the technical solutions of this application. Therefore, any simple modification, equivalent change, and embellishment made on the foregoing embodiments according to the technical essence of this application without departing from the content of the technical solutions of the present invention shall fall within the scope of the technical solutions of this application.

What is claimed is:

1. A display panel, comprising:
a first substrate, comprising an external surface and an internal surface;
a second substrate, disposed opposite to the first substrate, and having an external surface and an internal surface;
a color light filtering layer, disposed on the internal surface either of the first substrate or of the second substrate in an arrayed pattern; and
a light shielding layer, disposed on the external surface of the first substrate, wherein the light shielding layer comprises a first light shielding layer disposed at an edge of the first substrate, and a second light shielding layer arrayed on an internal side of the edge of the first substrate, the second light shielding layer being surrounded by the first light shielding layer;
wherein the second light shielding layer is disposed corresponding to a gap of the arrayed pattern of the color light filtering layer.

2. The display panel according to claim 1, wherein the light shielding layer is a black matrix.

3. The display panel according to claim 2, wherein the black matrix is an organic insulation material.

4. The display panel according to claim 3, wherein the organic insulation material is a photosensitive resin material.

5. The display panel according to claim 3, wherein the photosensitive resin material is a metal material.

6. The display panel according to claim 1, wherein the color light filtering layer comprises a first color light filter, a second color light filter and a third color light filter formed in parallel.

7. The display panel according to claim 6, wherein the first color light filter is a red light filter, the second color light filter is a green light filter, and the third color light filter is a blue light filter.

8. The display panel according to claim 1, wherein the first substrate is a switch array substrate.

9. The display panel according to claim 1, wherein the second substrate is a color light filter substrate.

10. The display panel according to claim 1, further comprising a flat layer, disposed on the external surface of the first substrate.

11. A display apparatus, comprising:
a backlight module; and
a display panel, comprising:
a first substrate, comprising an external surface and an internal surface;
a second substrate, disposed opposite to the first substrate, and having an external surface and an internal surface;
a color light filtering layer, disposed on the internal surface either of the first substrate or of the second substrate in an arrayed pattern; and
a light shielding layer, disposed on the external surface of the first substrate, wherein the light shielding layer comprises a first light shielding layer disposed at an edge of the first substrate, and a second light shielding layer arrayed on an internal side of the edge of the first substrate, the second light shielding layer being surrounded by the first light shielding layer;
wherein the second light shielding layer is disposed corresponding to a gap of the arrayed pattern of the color light filtering layer.

12. The display apparatus according to claim 11, wherein the light shielding layer is a black matrix.

13. The display apparatus according to claim 12, wherein the black matrix is an organic insulation material.

14. The display apparatus according to claim 13, wherein the organic insulation material is a photosensitive resin material.

15. The display apparatus according to claim 11, wherein the color light filtering layer comprises a first color light filter, a second color light filter and a third color light filter formed in parallel.

16. The display apparatus according to claim 15, wherein the first color light filter is a red light filter, the second color light filter is a green light filter, and the third color light filter is a blue light filter.

17. The display apparatus according to claim 11, wherein the first substrate is a switch array substrate.

18. The display apparatus according to claim 11, wherein the second substrate is a color light filter substrate.

19. A display apparatus according to claim 11, further comprising a flat layer, disposed on the external surface of the first substrate.

20. A display panel, comprising:
a first substrate, comprising an external surface and an internal surface;
a color light filtering layer, disposed on the internal surface of the first substrate in an arrayed pattern; and
a light shielding layer, disposed on the external surface of the first substrate, wherein the light shielding layer comprises a first light shielding layer disposed at an edge of the first substrate, and a second light shielding layer arrayed on an internal side of the edge of the first substrate, the second light shielding layer being surrounded by the first light shielding layer;
wherein the second light shielding layer is disposed corresponding a gap of the arrayed pattern of the color light filtering layer;
wherein the light shielding layer is a black matrix, and the black matrix is photosensitive resin material or a metal material;
wherein the color light filtering layer comprises a first color light filter, a second color light filter and a third color light filter formed in parallel, and the first color light filter is a red light filter, the second color light filter is a green light filter, and the third color light filter is a blue light filter.
